(19) United States
(12) Patent Application Publication
(10) Pub. No.: US 2024/0387225 A1
(43) Pub. Date: Nov. 21, 2024

(54) ELECTROSTATIC CHUCKS AND RELATED METHODS

(71) Applicant: ENTEGRIS, INC., Billerica, MA (US)

(72) Inventor: Carlo Waldfried, Middleton, MA (US)

(21) Appl. No.: 18/651,833

(22) Filed: May 1, 2024

Related U.S. Application Data
(60) Provisional application No. 63/467,041, filed on May 17, 2023.

(51) Int. Cl. H01L 21/683; B33Y 10/00; B33Y 40/20; B33Y 80/00; H05B 3/28

(52) U.S. Cl. CPC H01L 21/6833; B33Y 10/00; B33Y 40/20; B33Y 80/00; H05B 3/28

(57) ABSTRACT

A device may include an additive manufactured monolithic structure including an insulating body and at least one conductive region located in the insulating body. The additive manufactured monolithic structure does not include a bonding component between the insulating body and the at least one conductive element. The additive manufactured monolithic structure may further include at least one conduit that is free from any material. The insulating body may include a ceramic material and the at least one conductive region may include a metal material, such that the ceramic material and the metal material are co-deposited layer by layer to form the additive manufactured monolithic structure.

### CROSS-REFERENCE TO RELATED APPLICATION

This application claims the benefit of and priority to U.S. Provisional Application No. 63/467,041, filed on May 17, 2023, which is incorporated herein by reference in its entirety for all purposes.

### FIELD

This disclosure relates to electrostatic chucks and more particularly electrostatic chucks capable of withstanding high temperatures and methods of manufacturing the same.

### BACKGROUND

Electrostatic chucks are used to hold and support a substrate in a fixed position by an electrostatic force during semiconductor processes. The construction of conventional chucks is based on the fabrication of individual components and subsequent bonding of these components together. Conventional chucks exhibit poor performance at high temperatures due to bond failure and the corresponding loss in mechanical and structural integrity. Performance of conventional chucks also suffers from disproportional heat loss and limitations in the arrangement of heater elements within the chuck.

### SUMMARY

Some embodiments relate to an electrostatic chuck including an additive manufactured monolithic structure including an insulating body and at least one conductive element located in the insulating body.

In some embodiments, the additive manufactured monolithic structure does not include a bonding component between the insulating body and the at least one conductive element.

In some embodiments, the additive manufactured monolithic structure further comprises at least one conduit, wherein the at least one conduit is defined by the insulating body and is free of any material.

In some embodiments, the at least one conduit is a thermal shield structure within the insulating body. In some embodiments, the thermal shield structure is coextensive with and adjacent to an outer perimeter of the insulating body.

In some embodiments, the at least one conduit is at least one of a gas channel, a liquid channel, a connecting hole, a screw hole, a through-hole, a void, or any combination thereof.

In some embodiments, the insulating body includes a ceramic material and the at least one conductive element includes a metal material.

In some embodiments, an electrostatic chuck, wherein the ceramic material and the metal material are deposited layer by layer to form the additive manufactured monolithic structure.

In some embodiments, the insulating body includes at least one of: alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combinations thereof.

In some embodiments, the at least one conductive element includes at least one of: aluminum, tungsten, nickel, stainless steel, silver, gold, tantalum, platinum, palladium, cobalt, titanium, copper, molybdenum, silicon, molybdenum disilicide, or any combinations thereof.

In some embodiments, the insulating body has a resistivity of not less than about 10¹¹ Ohm-cm.

In some embodiments, the at least one conductive element includes at least one electrode, the at least one electrode is configured to produce an electrostatic field in response to an electrical charge.

In some embodiments, the at least one conductive element extends from a second side of the insulating body towards a first side of the insulating body such that the at least one electrode substantially extends along a plane adjacent the first side within the insulating body.

In some embodiments, the at least one electrode includes a plurality of electrodes, the plurality of electrodes includes separate electrically conducting pathways extending through the insulating body from a second side of the insulating body and towards a first side of the insulating body such that the plurality of electrodes substantially extend along a plane adjacent the first side within the insulating body.

In some embodiments, the at least one conductive element further includes at least one heating element, the at least one heating element is configured to provide thermal energy to the additive manufactured monolithic structure.

In some embodiments, the at least one conductive element includes a plurality of heating elements, the plurality of heating elements include separate electrically conducting pathways extending through the insulating body from a second side of the insulating body to different regions of the additive manufactured monolithic structure to provide localized thermal energy to the insulating body.

In some embodiments, the plurality of heating elements are located below the at least one electrode in the insulating body.

In some embodiments, the plurality of heating elements are further located adjacent a sidewall within the insulating body.

In some embodiments, the plurality of heating elements are arranged in a horizontal direction and/or a vertical direction within the insulating body to obtain a desired thermal uniformity at a first side of the insulating body.

In some embodiments, the at least one conductive element includes a temperature measurement probe, a thermocouple, a resistant temperature detector, or other temperature sensing device.

In some embodiments, the at least one conductive element includes a plurality of temperature measurement probes, wherein each of the plurality of temperature measurement probes include separate electrically conducting pathways extending through the insulating body from a second side towards a first side of the insulating body.

In some embodiments, the at least one conductive element includes a dummy structure to provide more uniform thermal, electrical or physical performance of the electrostatic chuck.

In some embodiments, the at least one conductive element includes a plurality of electrodes, a plurality of heating elements, and a plurality of temperature measurement probes, each of the plurality of electrodes, the plurality of heating elements, and the plurality of temperature measurement probes have separate electrically conducting pathways through the insulating body from a second side towards a first side of the insulating body.

In some embodiments, the at least one conduit includes a lift pin hole defined by the insulating body.

In some embodiments, the at least one conduit includes a backside gas delivery hole defined by the insulating body.

In some embodiments, the at least one conduit includes a dummy structure defined by the insulating body, the dummy structure is configured to provide uniform thermal, electrical or physical performance of the electrostatic chuck.

In some embodiments, the at least one conduit includes a gas channel defined by the insulating body.

In some embodiments, the at least one conduit includes at least one of a mounting fixture, bolt hole, flange, connector, alignment feature, optical pathway, or any combinations thereof.

In some embodiments, a first side of the insulating body includes a structured pattern including a plurality of gas channels.

In some embodiments, the additive manufactured monolithic structure further includes at least one gas channel disposed at a first side of the insulating body.

In some embodiments, a first side of the insulating body includes a structured pattern including a plurality of embossments.

In some embodiments, the plurality of embossments are formed by a coating applied to the first side of the insulating body.

In some embodiments, the coating is polished to provide at least one of improved planarity, improved surface finish, improved density, improved precision of insulating layer thickness between the at least one conductive element and the first side, or any combinations thereof.

In some embodiments, the coating further includes at least one of: a dielectric layer, a metal diffusion barrier layer, a dielectric breakdown prevention layer, a mechanical wear resistant layer, or any combinations thereof.

Some embodiments relate to a method comprising one or more of the following steps: depositing a ceramic material so as to form an insulating body, and depositing a metal material so as to form at least one conductive element located in the insulating body. In some embodiments, the ceramic material and the metal material are co-printed layer by layer to form an additive manufactured monolithic structure.

In some embodiments, the method further comprises applying a coating onto a top surface of the insulating body.

In some embodiments, the method further comprises at least one of the following steps: forming a plurality of embossments on a top surface of the insulating body; polishing a top surface of at least a portion of the plurality of embossments; forming a coating on at least one of the following: the top surface of at least a portion of the plurality of embossments, the top surface of the insulating body, or any combination thereof; or any combination thereof.

In some embodiments, the coating is at least one of a dielectric layer, a metal diffusion barrier layer, a dielectric breakdown prevention layer, a mechanical wear resistant layer, or any combination thereof.

Some embodiments relate to a method including depositing a ceramic material so as to form an insulating body, depositing a metal material so as to form at least one conductive element located in the insulating body that extends from a second side towards a first side of the insulating body, wherein the ceramic material and the metal material are co-printed layer by layer to form an additive manufactured monolithic structure.

In some embodiments, the method further includes applying a coating onto the first side of the insulating body, the coating includes at least one of: a dielectric layer, a metal diffusion barrier layer, a dielectric breakdown prevention layer, a mechanical wear resistant layer, or any combinations thereof.

In some embodiments, the method further includes polishing the coating on the first side of the insulating body, the coating is polished to provide at least one of: improved planarity, improved surface finish, improved density, improved precision of insulating layer thickness between the at least one conductive element and the first side, or any combinations thereof.

In some embodiments, the method further includes forming a structured pattern on the first side of the insulating body, wherein the structured pattern includes a plurality of embossments.

### BRIEF DESCRIPTION OF THE DRAWINGS

The disclosure may be more completely understood in consideration of the following description of various illustrative embodiments in connection with the accompanying drawings.

FIG. 1 is a flowchart of a method for forming an electrostatic chuck, according to some embodiments.

FIG. 2 is a perspective view of a non-limiting embodiment of a device, according to some embodiments.

FIG. 3 is a cross-sectional side view of a non-limiting embodiment of a device, according to some embodiments.

FIG. 4 is an exploded view of a non-limiting embodiment of an electrostatic chuck.

FIGS. 5-6 are schematics views of different layers included in the non-limiting embodiment of the electrostatic chuck shown in FIG. 4.

FIG. 7 is a side-cross sectional view of the electrostatic chuck of FIG. 4.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “between” does not necessarily require being disposed directly next to other elements. Generally, this term means a configuration where something is sandwiched by two or more other things. At the same time, the term “between” can describe something that is directly next to two opposing things. Accordingly, in any one or more of the embodiments disclosed herein, a particular structural component being disposed between two other structural elements can be:
disposed directly between both of the two other structural elements such that the particular structural component is in direct contact with both of the two other structural elements; disposed directly next to only one of the two other structural elements such that the particular structural component is in direct contact with only one of the two other structural elements;
disposed indirectly next to only one of the two other structural elements such that the particular structural component is not in direct contact with only one of the two other structural elements, and there is another element which juxtaposes the particular structural component and the one of the two other structural elements;
disposed indirectly between both of the two other structural elements such that the particular structural component is not in direct contact with both of the two other structural elements, and other features can be disposed therebetween; or any combination(s) thereof.

As used herein, the term “embedded” refers to a first material that is distributed throughout and/or within a second material. In some embodiments, the term refers to a first material that is partially encapsulated in a second material. In some embodiments, the term refers to a first material that is fully encapsulated in a second material. In some embodiments, the term refers to a first material that is not exposed to an external environment.

As used herein, the term “depositing” refers to the formation of a 3D object by applying one or more materials, such as a filament, during an additive manufacturing process. The one or more materials are added one layer at a time and a fusing application is used to bind the layers to form a monolithic structure. In some embodiments, the term “depositing” can be disposing, printing, co-printing, jetting, ejecting, or the like.

Conventional chucks require bonding agents to maintain structural integrity between different components (e.g., insulative layers, conductive layers, dielectric layers, etc.) of the conventional chuck. The operable temperature range over which conventional chucks can be used is limited by, among other things, the bonding agent, which degrades or otherwise deteriorates at elevated temperatures. Accordingly, conventional chucks with these bonding agents are not suitable for use at high temperatures because, when the bonding agent degrades or deteriorates, a corresponding loss in structural integrity and mechanical integrity of the conventional chuck is observed.

Embodiments disclosed herein overcome at least the problems of conventional chucks by providing, among other things, electrostatic chucks comprising a monolithic structure that does not require or include any bonding agents after the manufacturing process of the electrostatic chuck is complete. In some cases, the monolithic structure may include a conduit. Such conduits present within a monolithic structure are not achievable with conventional manufacturing techniques. Additionally, the removal of the bonding agent, or more generally bonding component, provides numerous advantages, including broadening of the operable temperature range over which the electrostatic chuck can be used. For example, the electrostatic chucks disclosed herein are capable of operating at high temperatures, such as, for example and without limitation, temperatures of 500° C. or greater, without any corresponding loss in structural and/or mechanical integrity. As used herein, the term “bonding component” refers to a bond other than a bond formed via an additive manufacturing process. For example, in some embodiments, the term “bonding component” does not refer to a bond formed via an additive manufacturing process.

At least another advantage of the electrostatic chucks disclosed herein is that the electrostatic chucks can maintain thermal uniformity across a wafer surface to the wafer edge, while operating at high temperatures. Conventional chucks typically suffer from disproportionate, non-uniform heat loss across the wafer surface and an inability to provide adequate heating power at the wafer edge. Embodiments overcome at least the challenges of conventional chucks by providing electrostatic chucks capable of being constructed so as to compensate for temperature non-uniformities in the electrostatic chuck. For example, in some embodiments, electrostatic chucks can be constructed via additive manufacturing to include one or more heat conductive elements in locations of the insulating body that compensate for the aforementioned temperature non-uniformities. At least another further advantage of the electrostatic chucks disclosed herein is that the electrostatic chucks minimize or avoid metal contamination due to the diffusion of impurities at high temperatures.

Accordingly, various embodiments of the disclosure provide electrostatic chucks formed by additive manufacturing and methods of forming electrostatic chucks by additive manufacturing.

Some embodiments relate to an electrostatic chuck including an insulating body and at least one conductive element. The at least one conductive element is formed from one or more metal materials and can be located within (e.g., embedded in) the insulating body to provide thermal uniformity at the surface of the electrostatic chuck and/or to provide optimal dimensions for emitting an electric field. In some embodiments, the insulating body comprises a ceramic material. In some embodiments, the ceramic material is configured to be an insulating layer located between two or more conductive elements. In some embodiments, the ceramic material is configured to be a dielectric layer located between at least one electrode and a top surface of the insulating body. In some embodiments, the electrostatic chuck further comprises a dielectric coating layer located on a top surface of the insulating body, a top surface of the plurality of embossments, or any combination thereof. In some embodiments, the electrostatic chuck further comprises a plurality of embossments located on a top surface of the insulating body, wherein the plurality of embossments is formed of a dielectric material. Additionally, the additive manufacturing process may provide for drop deposition with control over material thickness and dimensions such that the ceramic material deposited between the conductive elements (e.g., electrodes, heating elements, etc.) may serve as a dielectric layer and may also be deposited at the top region to serve as the embossment structure. In some embodiments, the electrostatic chuck is embedded with one or more features located and dimensioned to operate at said high temperatures, formed during a single application (e.g., one print), or any combination thereof.

Some embodiments relate to a device comprising an electrostatic chuck comprising an insulating body and a at least one conductive element. In some embodiments, the electrostatic chuck is an additive manufactured monolithic structure. In some embodiments, the additive manufactured monolithic structure does not comprise a bonding component between the insulating body and the at least one conductive element. In this regard, the electrostatic chuck may be capable of operating at temperatures at or above 500° C. while maintaining thermal uniformity at a surface of the electrostatic chuck. The extent to which the monolithic structure maintains thermal uniformity may be predetermined by arranging the at least one conductive element located in the insulating body. In some embodiments, following fabrication of the electrostatic chuck by additive manufacturing, the electrostatic chuck may be subjected to a deposition process, such as an atomic layer deposition (ALD) process or a thermal ALD process, in which one or more surfaces of the electrostatic chuck is coated with one or more layers. In some embodiments, the deposition process is sufficient to coat all exposed surfaces of the additive manufactured device.

The additive manufactured electrostatic chuck may not comprise a bonding component. In this regard, as the monolithic structure of the electrostatic chuck does not include a bonding component within the monolithic structure, the electrostatic chuck is capable of operating at temperatures at or above 500° C. without compromising the integrity of the monolithic structure. In some embodiments, the additive manufactured electrostatic chuck also does not comprise a bonding component between the ceramic component and the metal component. In some embodiments, the additive manufactured electrostatic chuck comprises one or more layers formed by selective drop deposition where the droplets are selectively bonded to form the one or more layers resulting in the formation of the monolithic structure. The one or more layers are bonded to adjacent layers during the formation of the electrostatic chuck through selective application of fusing processes such that the binding material is burned off as a result of the fusing process, thereby resulting in a monolithic structure comprising ceramic material, metal material, or a combination thereof. Accordingly, the electrostatic chuck may be formed such that the monolithic structure does not include a bonding component present between the one or more layers. In some embodiments, the electrostatic chuck may not comprise a bonding component between the insulating body and the at least one conductive region. In some embodiments, the processes applied during the deposition process may include, but is not limited to, at least one of heat, pressure, electrical process, ultrasonic vibrations, lasers, or any combination thereof.

Although the electrostatic chuck is capable of operating at temperatures of 500° C. or greater, in some embodiments, the temperature range over which the electrostatic chuck is used may be between 0-1000° C., or any range or subrange therebetween. For example, in some embodiments, the operating temperature may be 100-1000° C., 100-650° C., 200-650° C., 300-650° C., 400-650° C., 500-650° C., 100-550° C., 200-550° C., 300-550° C., 400-550° C., 500-550° C., 100-450° C., 200-450° C., 300-450° C., or 400-450° C. In some embodiments, the operating temperature of the electrostatic chuck may be 500° C. or greater. For example, in some embodiments, the electrostatic chuck is configured to operate at temperatures of 500° C. to 1000° C., or any range or subrange therebetween.

In various embodiments according to the present disclosure, the electrostatic chuck includes a monolithic structure formed by additive manufacturing forming a single structure having a unitary construction. In some cases, the monolithic structure can be a multi-layered structure, each layer of the multilayered structure being formed from a different material or combination of materials. Additionally, each layer of the multilayer monolithic structure can include different elements or features. For example, a middle layer can include a heater element, another layer can include at least one electrode, while yet another layer includes a conduit or void having no material. A top layer of the electrostatic chuck can include embossments and/or a dielectric layer while a bottom layer can include electrical contacts for facilitating an electrical connection to the electrostatic chuck. Each of these layers of the multilayer monolithic structure can be formed using an additive manufacturing process. In some embodiment, each layer of the electrostatic chuck is formed in a single additive manufacturing process (i.e. a single print) such that there is no distinct interface between the different layers but rather, a gradient where a first material or combination of materials transitions to a second material or combination of materials.

In some embodiments, the monolithic structure is formed by additive manufacturing and can include one or more regions formed from one or more materials. Each of the one or more materials may be selected, at least in part, on their ability to withstand high temperatures without compromising the structural integrity of the monolithic structure, without being susceptible to mechanical deformation, without materially impacting the monolithic structure's ability to provide thermal uniformity at various operating temperatures, and other similar features. In some embodiments, a monolithic structure comprises an additive manufactured structure formed from deposition of a first material to form a body and a second material to form one or more conductive elements within the body. Each of the first material and second material may be selected, in part, on their thermal properties and whether such materials are capable of operating at high temperatures once formed into the monolithic structure. Additionally, in some embodiments, the first material and second material are co-printed by additive manufacturing. In some embodiments, the first material and the second material may be applied in successive layers, where each layer includes the first material, the second material, or both, to form a monolithic structure of unitary constructure and thus are not separately manufactured and joined together post-manufacture (e.g., post-fabrication). In some embodiments, a monolithic structure comprises a three-dimensional (“3D”) structure formed from one or more materials selectively deposited during a deposition (e.g., co-printed) of each layer to form a first region and a second region located or embedded within the first region. In this regard, the first material and second material may be co-printed to form a monolithic structure where the first material forms an insulating body and the second material forms at least one conductive element distributed on, and/or within the insulating body based on one or more operating parameters of the monolithic structure. In an exemplary embodiment, the at least one conductive element can include a heating element that is distributed across the insulating body and/or distributed along the sidewalls of the monolithic structure. In another embodiment, the at least one conductive element can include at least one heating element distributed within the insulating body.

The monolithic structure that results from the additive manufacturing process does not include any bonding components such that the monolithic structure is a single structure having a unitary construction. In some embodiments, a monolithic structure comprises an additive manufactured structure that is not capable of construction by machining. In some embodiments, a monolithic structure comprises an additive manufactured structure that does not include any seams, weld joints, braze joints, or any combination thereof. Other techniques for forming monolithic structures, such as those formed with bonding components, seams, weld joints, braze joints, and other like methods, do not provide a monolithic structure having a unitary construction, and also may not be capable of operating at such high temperatures. Additionally, although other techniques exist for forming semiconductor process tool components, such as through sintering or glass fritz, these techniques do not form a monolithic structure as described in the present disclosure, but instead involve separate and/or independent formation of components and subsequent bonding together of the components post-manufacturing.

Additive manufacturing may comprise selectively co-printing a ceramic material and a metal material to form a monolithic structure. In some embodiments, the monolithic structure comprises a ceramic component formed from ceramic material and a metal component formed from metal material. In some embodiments, the ceramic component comprises an insulating body and the metal component comprises a at least one conductive element located in the insulating body. In some embodiments, the at least one conductive element may be arranged in predetermined locations of the monolithic structure. In some embodiments, for example, the electrostatic chuck may comprise a heat conductive element forming a heat conductive region in the insulating body and arranged to provide thermal uniformity from edge to edge of the electrostatic chuck and to the wafer. In another example, the plurality of heat conductive elements may include sidewall heaters to improve thermal capabilities at an edge of the electrostatic chuck.

In some embodiments, the at least one conductive element may comprise dimensions based on a desired operating characteristic of the electrostatic chuck. For example, the at least one conductive element may include dimensions for optimizing thermal uniformity of the electrostatic chuck based on the dimensions of the insulating body. Accordingly, dimensions and arrangement of the insulating body and the at least one conductive element of the electrostatic chuck is not intended to be limiting and may include any of a plurality of dimensions and arrangements based on an application, an operational characteristic (e.g., thermal characteristics, clamping force, electrical resistance, and the like), or any combination thereof.

The electrostatic chuck may be configured for securing a substrate to a side of the electrostatic chuck by application of an electrostatic force. The electrostatic force may be sufficient for securing the substrate to a surface of the electrostatic chuck. That is, in some embodiments, the substrate may be secured to the electrostatic chuck without application of any mechanical force, such as, for example and without limitation, mechanical clamps. In some embodiments, mechanical force may be applied to secure the substrate (e.g., via mechanical clamps). The substrate which is secured to the electrostatic chuck is not particularly limited and may include, for example and without limitation, a wafer, a workpiece, or any combination thereof. In some embodiments, the substrate comprises a semiconductor wafer. In some embodiments, the substrate comprises a silicon wafer. It will be appreciated that other substrates may be used herein without departing from the scope of this disclosure.

In some embodiments, the electrostatic chuck comprises an insulating body. The insulating body may comprise a ceramic component. In some embodiments, the insulating body may comprise a ceramic matrix. In some embodiments, the insulating body may be formed from ceramic materials. The ceramic materials may comprise at least one of alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combinations thereof.

In some embodiments, the electrostatic chuck comprises at least one conductive element. The at least one conductive element may comprise a metal component. In some embodiments, the metal component may be formed from metal materials. The metal materials may comprise at least one of aluminum, tungsten, nickel, stainless steel, silver, gold, tantalum, platinum, palladium, cobalt, titanium, copper, molybdenum, silicon, molybdenum disilicide, or any combinations thereof. In some embodiments, the metal component may comprise 17-4PH stainless steel, 316L stainless steel, other alloys, or any combination thereof.

The at least one conductive element may comprise a heating element, an electrode, a temperature measurement probe, a charge dissipation component (e.g., a grounding component), or any combination thereof. The heating element is configured to provide thermal energy to the insulating body. In some embodiments, the at least one conductive element may comprise a plurality heating elements having separate electrically conducting pathways extending through the insulating body from a second side of the insulating body to different regions of the insulating body to provide localized thermal energy to the insulating body and to the top surface. In some embodiments, the plurality of heating elements is arranged in the monolithic structure to control a temperature of the electrostatic chuck. In some embodiments, for example, an electrostatic chuck may comprise a monolithic structure having a first side, a second side, and at least one sidewall, and one or more heat conductive regions embedded within the monolithic structure. In some embodiments, the one or more heat conductive regions is located between the first side and the second side of the electrostatic chuck. In some embodiments, at least one of the one or more heat conductive regions circumferentially extends along and/or adjacent to a sidewall of the electrostatic chuck. In some embodiments, the at least one heating element is a plurality of heating elements, at least two of the plurality of heating elements having at least one of a different cross-sectional area, a different cross-sectional shape, a different location within the insulating body (e.g., relative location between first side and second side), or any combination thereof. In some embodiments, at least one of the cross-sectional areas, the cross-sectional shape, the location within the insulating body, or any combination thereof is varied to optimize a temperature profile on a surface of the electrostatic chuck.

The electrode is configured to produce an electrostatic field in response to an electrical charge. The electrode extends from a bottom surface, of the insulating body towards a top surface of the insulating body such that the electrode substantially extends along a plane adjacent and below the top surface of the insulating body. In some embodiments, the at least one conductive region may comprise a plurality of electrodes having separate electrically conducting pathways extending through the insulating body from a bottom surface of the insulating body and towards a first side of the insulating body such that the plurality of electrodes substantially extend along a plane adjacent the first side within the insulating body. In some embodiments, the plurality of electrodes (e.g., one or more electrodes) is arranged in the monolithic structure to provide an electrostatic force to secure a substrate onto the electrostatic chuck. In some embodiments, for example, an electrostatic chuck may comprise one or more electrodes arranged adjacent to a plurality of embossments below a top surface of the electrostatic chuck.

The temperature measurement probe measures a temperature of the monolithic structure. In some embodiments, the temperature measurement probe includes a thermocouple, a resistant temperature detector, or any combination thereof. In some embodiments, the at least one conductive element may include a plurality of temperature measurement probes having separate electrically conducting pathways extending through the insulating body from a bottom surface and towards a top surface of the insulating body. In some embodiments, the monolithic structure may further comprise at least one terminal in communication with the at least one conductive element. In some embodiments, the monolithic structure may further comprise at least one terminal in communication with the plurality of heating elements, plurality of electrodes, plurality of temperature measurement probes, or any combinations thereof.

The electrostatic chuck may not comprise the bonding component between the insulating body and the at least one conductive element. In some embodiments, the electrostatic chuck does not comprise the bonding component between the insulating body and the heating element. In some embodiments, the electrostatic chuck does not comprise the bonding component between the insulating body and the electrode. In some embodiments, the electrostatic chuck does not comprise the bonding component between the insulating body and the temperature measurement probe. In some embodiments, the electrostatic chuck does not comprise the bonding component between the heating element, the electrode, and the temperature measurement probe.

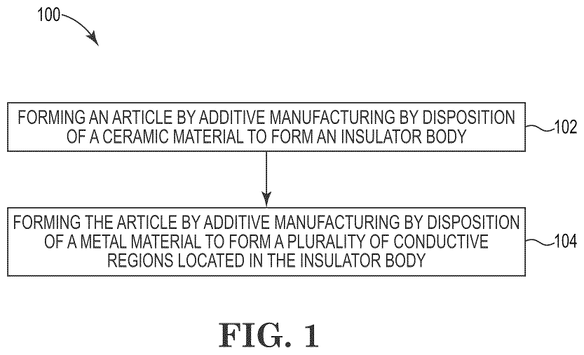

FIG. 1 is a flowchart of a method for forming an electrostatic chuck, according to some embodiments of the present disclosure. As shown in FIG. 1, the method 100 for forming an electrostatic chuck having an additive manufactured monolithic structure may comprise one or more of the following steps: a step 102 of depositing a ceramic material so as to form an insulating body, a step 104 of depositing a metal material so as to form at least one conductive element located in the insulating body that extends from a second side towards a first side of the insulating body. In some embodiments, the depositing of the ceramic material and the depositing of the metal material is performed simultaneously (e.g. co-printing). In some embodiments, the disposing of the ceramic material and the disposing of the metal material is performed sequentially. In some embodiments, the ceramic material and the metal material are co-printed such that the metal material is located or embedded within the ceramic material.

At step 102, the method 100 may comprise depositing a ceramic material so as to form an insulating body. At step 104, the method 100 may comprise depositing a metal material so as to form a at least one conductive element located in the insulating body. The at least one conductive element extends from a second side of the insulating body and towards a first side of the insulating body while being located within an interior region of the insulating body such that the at least one conductive element does not protrude from the at least one sidewall and the top surface of the insulating body. In some embodiments, the ceramic material and the metal material are co-printed layer by layer to form an additive manufactured monolithic structure including an insulating body and at least on conductive element within the insulating body.

In some embodiments, the ceramic material and the metal material are co-printed during a single application process such that each layer may include the ceramic material, the metal material, or both. In some embodiments, the at least one conductive element may comprise a heating element, an electrode, a temperature measurement probe, or any combination thereof. In some embodiments, the electrostatic chuck is formed such that the monolithic structure does not comprise a bonding component between the insulating body and the at least one conductive element. In some embodiments, the electrostatic chuck may include one or more heating elements configured to operate at or above 500° C. during a semiconductor manufacturing process. In some embodiments, the electrostatic chuck may include one or more heating elements configured to operate at room temperature, or a temperature in a range of 20° C. to 1200° C., 100° C. to 1200° C., 200° C. to 1200° C., 300° C. to 1200° C., 400° C. to 1200° C., 500° C. to 1200° C., 600° C. to 1200° C., 700° C. to 1200° C., 800° C. to 1200° C., 900° C. to 1200° C., 1000° C. to 1200° C., 1100° C. to 1200° C., 20° C. to 1100° C., 20° C. to 1000° C., 20° C. to 900° C., 20° C. to 800° C., 20° C. to 700° C., 20° C. to 600° C., 20° C. to 500° C., 20° C. to 400° C., 20° C. to 300° C., 20° C. to 200° C., 20° C. to 100° C., or 20° C. to 50° C. As such, the monolithic structure of the electrostatic chuck is formed from the ceramic material and the metal material and does not include a bonding component therebetween to enable the electrostatic chuck to operate at temperatures at or above 500° C. during the semiconductor manufacturing process without causing degradation to the structural integrity of the electrostatic chuck.

The additive manufacturing may comprise 3D printing. In some embodiments, the electrostatic chuck may comprise a 3D electrostatic chuck formed by dispensing one or more 3D printable materials from a 3D printer to form the 3D electrostatic chuck. In some embodiments, the 3D printing may comprise creating a solid object from a 3D model by building the object incrementally. In some embodiments, for example, 3D printing may comprise applying the 3D printable materials in layers which are selectively joined or fused together to create a 3D electrostatic chuck having at least one of a monolithic structure, a unitary construction, a structure not capable of construction by machining, or any combination thereof. The 3D printing may include a fusing application using at least one of the following: selective laser melting (SLM), selective laser sintering (SLS), fused deposition modeling (FDM), electron beam melting (EBM), direct metal laser sintering (DMLS), multi-material jetting, or any combination thereof.

The additive manufacturing may comprise a multi material jetting process. In some embodiments, the multi material jetting process may comprise selective drop deposition of one or more materials. In some embodiments, the material may comprise a precursor material. In some embodiments, additive manufacturing may comprise solidification by cooling of the material deposited during the additive manufacturing. In some embodiments, the multi material jetting process may comprise selective drop deposition of an electrostatic chuck-filled thermoplastic feedstock comprising a precursor material. In some embodiments, the multi material jetting process may comprise the selective application of one or more of the precursor materials applied by a printhead capable of selectively depositing one or more of the precursor materials during the additive manufacturing process. In some embodiments, for example, the printhead may be capable of depositing up to four materials, such as three precursor materials and a support material.

The drop volume may be a volume of 0.5 nl to 45 nl, or any range or subrange between 0.5 nl to 45 nl. For example, in some embodiments, the drop volume of a precursor material may be 0.5 nl to 45 nl, 1 nl to 45 nl, 5 nl to 45 nl, 10 nl to 45 nl, 15 nl to 45 nl, 20 nl to 45 nl, 25 nl to 45 nl, 30 nl to 45 nl, 35 nl to 45 nl, 0.5 nl to 30 nl, 1 nl to 30 nl, 5 nl to 30 nl, 10 nl to 30 nl, 15 nl to 30 nl, 20 nl to 30 nl, 25 nl to 30 nl, 0.5 nl to 20 nl, 1 nl to 20 nl, 5 nl to 20 nl, 10 nl to 20 nl, or 15 nl to 20 nl.

The droplet diameter may be a diameter of 200 μm to 1000 μm, or any range or subrange between 200 μm to 1000 μm. For example, in some embodiments, the droplet diameter of a precursor material may be 200 μm to 1000 μm, 200 μm to 900 μm, 200 μm to 800 μm, 200 μm to 700 μm, 200 μm to 600 μm, 200 μm to 500 μm, 200 μm to 400 μm, 200 μm to 300 μm, 300 μm to 1000 μm, 300 μm to 900 μm, 300 μm to 800 μm, 300 μm to 700 μm, 300 μm to 600 μm, 300 μm to 500 μm, 300 μm to 400 μm, 400 μm to 1000 μm, 400 μm to 900 μm, 400 μm to 800 am, 400 μm to 700 μm, 400 μm to 600 μm, 400 μm to 500 μm, 500 μm to 1000 μm, 500 μm to 900 μm, 500 μm to 800 μm, 500 μm to 700 μm, 500 μm to 600 μm, 600 μm to 1000 μm, 600 μm to 900 μm, 600 μm to 800 μm, 600 μm to 700 μm, 700 μm to 1000 μm, 700 μm to 900 μm, 700 μm to 800 μm, 800 μm to 1000 μm, 800 μm to 900 μm, or 900 μm to 1000 μm. In some embodiments, the diameter may be less than 1000 μm.

The layer height of a precursor material may be a height of 70 μm to 300 μm, or any range or subrange between 70 μm to 300 μm. In some embodiments, a layer height of each layer of the electrostatic chuck 302 may be based on a layer height of a precursor material. For example, in some embodiments, the layer height of a precursor material may be 70 μm to 300 μm, 100 μm to 300 μm, 150 μm to 300 μm, 200 μm to 300 μm, 250 μm to 300 μm, 70 μm to 250 μm, 100 μm to 250 μm, 150 μm to 250 μm, 200 μm to 250 μm, 70 μm to 200 μm, 100 μm to 200 μm, 150 μm to 200 μm, 70 μm to 150 μm, or 100 μm to 150 μm.

The electrostatic chuck may be formed from a precursor material. In some embodiments, additive manufacturing may comprise deposition of filament feedstocks. In some embodiments, the filament feedstock may comprise a precursor material. In some embodiments, the precursor material may comprise a raw material, such as a granular raw material. For example, in some embodiments, the precursor material may comprise at least one of a metal powder, a metal alloy powder, a ceramic powder, a polymer (e.g., a photopolymer resin, a thermoplastic polymer, or any combination thereof), or any combination thereof. In some embodiments, the precursor material may comprise a material capable of being fused by heat (e.g., a scanning laser or scanning electron beam) such that the resulting monolithic structure consists essentially of ceramic material and metal material and does not include bonding materials. In some embodiments, the precursor material may comprise, consist of, or consist essentially of, or may be selected from a group consisting of, at least one of the following: a ceramic material, a metal material, a polymeric material, or any combination thereof.

The precursor material may comprise, consist of, or consist essentially of a ceramic material. In some embodiments, for example, the insulating body may comprise, consist of, or consist essentially of a ceramic material. In some embodiments, the ceramic material may comprise, consist of, or consist essentially of, or may be selected from a group consisting of, at least one of the following: alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium dioxide, chromium oxide, yttrium oxide, iron oxide, barium oxide, barium titanate, tantalum oxide, or any combination thereof. In some embodiments, the insulating body may comprise an electrically conductive ceramic material, a non-conductive ceramic material, or any combination thereof. In some embodiments, the insulating body has an electrical resistivity of not less than about 10¹¹ Ohm-cm. In some embodiments, for example, the insulating body may comprise silicon nitride—molybdenum disilicide and comprise an electrical resistivity of 1.6×10² Ohm-cm. In another example, the insulator may comprise silicon nitride—molybdenum disilicide and comprise an electrical resistivity of 2.4×10⁻² Ohm-cm. In some embodiments, the ceramic material may comprise a solid content of up to 50 vol. %.

The precursor material may comprise, consist of, or consist essentially of a metal material. In some embodiments, for example, a plurality of insulator regions may comprise, consist of, or consist essentially of a metal material. In some embodiments, the metal material may comprise, consist of, or consist essentially of at least one of one or more metals, one or more metal compounds, one or more metal oxides, one or more metal alloys, or any combination thereof. In some embodiments, the metal material may comprise, consist of, or consist essentially of, or may be selected from the group consisting of, at least one of the following: aluminum, tungsten, nickel, stainless steel, silver, gold, tantalum, platinum, palladium, cobalt, titanium, copper, molybdenum, silicon, or any combinations thereof. In some embodiments, for example, the metal material may comprise 316L stainless steel and comprise a solid content of 55 vol. %.

In some embodiments, the precursor material may comprise, consist of, or consist essentially of a polymer material. In some embodiments, the polymer material may comprise, consist of, or consist essentially of, or may be selected from a group consisting of, at least one of the following: waxes, polycaprolactone, thermoplastics, photopolymers, or any combination thereof. In some embodiments, the precursor material may further comprise one or more solvents.

The electrostatic chuck may comprise an additive manufactured 3D electrostatic chuck. In some embodiments, the electrostatic chuck may comprise an additive manufactured 3D body. In some embodiments, the electrostatic chuck may have a monolithic structure. In some embodiments, a monolithic structure may be a structure that does not comprise a bonding component between the insulating body and the at least one conductive element. In some embodiments, a monolithic structure may be a structure that is not capable of construction by glass bonding. In some embodiments, the monolithic structure may be a structure that is not capable of construction by forming a body from one or more materials (e.g., powder materials) using a mold and bonding the one or more materials using a fuse application such as glass bonding and/or sintering. In some embodiments, a monolithic structure may be a structure of unitary construction. In some embodiments, the electrostatic chuck may be of unitary construction. In some embodiments, the monolithic structure may be a structure that is not capable of construction by machining a raw workpiece to form the insulating body. In some embodiments, the term “unitary construction” may refer to a structure that does not comprise two or more structures joined together post-fabrication. For example, in some embodiments, the electrostatic chuck may not comprise any structures that are separately fabricated and subsequently joined together. In some embodiments, a monolithic structure of unitary construction may be at least one of a structure that does not comprise seams, a structure that does not comprise braze joints, a structure that does not comprise weld joints, or any combination thereof.

The electrostatic chuck may have at least one feature. The at least one feature may comprise, consist of, or consist essentially of, or may be selected from the group consisting of, a conduit, a channel, a plenum, a trench, a fitting, a connector, a seal ring, a chamber, a heat shield, a structure defining a hole, a structure defining an air gap, a structure defining a channel, a structure defining a cavity (e.g., a partially enclosed region defining a cavity), a planar surface, a non-planar surface, a plurality of embossments, at least one conductive element, or any combination thereof. In some embodiments, the at least one conductive element comprises electrodes, heating elements, temperature measurement probes, or any combination thereof. In some embodiments, the at least one feature may be embedded in the monolithic structure. In some embodiments, for example, the fittings may be a metal fitting embedded in a side of the insulating body and connected to one or more of the separate conductive pathways of the at least one conductive element. In some embodiments, the at least one feature may be defined by the insulating body. In some embodiments, for example, the electrostatic chuck may include at least one conduit that circumferentially extends through an interior of the insulating body adjacent a perimeter of the insulating body to provide uniform thermal, electrical, and physical performance of the electrostatic chuck.

Although not shown, in some embodiments, the method further comprises one or more of the following steps, which may optionally be performed: forming a structured pattern onto a top surface, e.g., first side, of the insulating body, applying a coating onto the top surface of the insulating body. In some embodiments, the structured pattern comprises an embossed surface. In other embodiments, the structured pattern comprises a plurality of embossments. In some embodiments, forming the embossed surface further comprises polishing a plurality of embossments on a surface of the electrostatic chuck. In some embodiments, forming the structured pattern further comprises a planarization of a top surface of the electrostatic chuck. In some embodiments, the coating comprises at least one of: a dielectric layer, a metal diffusion barrier layer, a dielectric breakdown prevention layer, a mechanical wear resistant layer, or any combinations thereof. In some embodiments, applying the coating further comprises polishing the coating on the first side of the insulating body. In some embodiments, the coating is polished to provide at least one of: improved planarity, improved surface finish, improved density, improved precision of insulating layer thickness between the at least one conductive element and the first side, or any combinations thereof. In some embodiments, for example, the coating may be a dielectric layer applied to the embossed surface of the electrostatic chuck. In another example, the coating may be a diffusion barrier layer applied to the embossed surface of the electrostatic chuck.

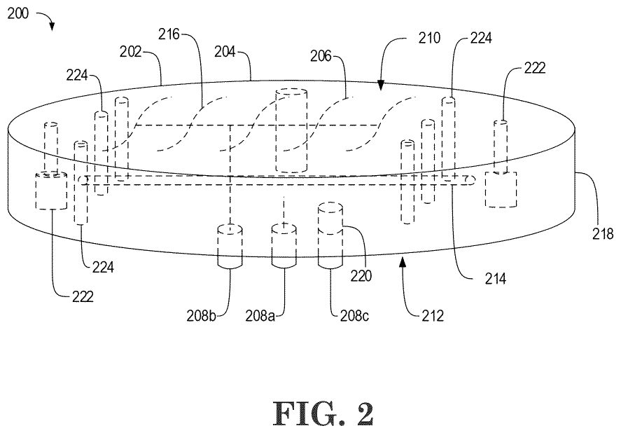

FIG. 2 is a perspective view of a non-limiting embodiment of a device 200, according to some embodiments. As shown in FIG. 2, the device 200 comprises a monolithic structure 202 comprising an insulating body 204 and at least one conductive element 206 located in the insulating body 204. The monolithic structure 202 is an additive manufactured monolithic structure 202 of unitary construction. In some embodiments, the monolithic structure 202 does not include a bonding component. In other embodiments, the monolithic structure 202 does not include a bonding component between the insulating body 204 and the at least one conductive element 206.

The insulating body 204 includes a first side 210 and a second side 212 opposite the first side 210. In some embodiments, the first side 210 may be referred to as a top surface and the second side 212 may be referred to as a bottom surface. In some embodiments, the at least one conductive element 206 may comprise an electrode, a heating element, a temperature measurement probe, or any combination thereof. In some embodiments, the at least one conductive element 206 may comprise a plurality of conductive elements that extend from the second side 212 towards the first side 210 of the insulating body 204 such that each of the conductive elements comprise separate electrically conducting pathways that extend through the insulating body 204 to achieve a desired performance characteristics for the device 200. In some embodiments, the at least one conductive element 206 may further comprise a dummy structure to provide more uniform thermal, electrical or physical performance of the device 200.

The monolithic structure 202 may comprise at least one terminal 208. The at least one terminal 208 enables at least one of an electrical current (e.g., AC, DC, non-AC, non-DC, or any combination thereof), an electrical potential (e.g., AC, DC, non-AC, non-DC, or any combination thereof), a ground connection, or any combination thereof to be applied to at least one conductive element 206.

In some embodiments, the monolithic structure 202 may include at least one first terminal 208a in communication with the heating element 214. In other embodiments, the at least one first terminal 208a may be in communication with the plurality of heating elements 214. In some embodiments, the monolithic structure 202 may include at least one second terminal 208b in communication with the electrode 216. In other embodiments, the at least one second terminal 208b may be in communication with the plurality of electrodes 216. In other embodiments, the monolithic structure 202 may include at least one third terminal 208c in communication with the temperature measurement probe 220. In other embodiments, the at least one third terminal 208c may be in communication with the plurality of temperature measurement probe 220. In some embodiments, for example, a first terminal may be in communication with one or more heating elements and a second terminal may be in communication with one or more electrodes in the insulating body and electrical current may be applied to the first terminal 208a to heat the electrostatic chuck and electrical current may be applied to the second terminal 208b to provide an electrostatic force to secure a wafer to a side of the electrostatic chuck.

In some embodiments, the at least one conductive element 206 may comprise a heating element 214. The heating element 214 extends from the second side 212 and throughout an interior portion of the insulating body 204 based on the desired thermal characteristics of the device 200. The heating element 214 is configured to generate thermal energy, e.g., heat, in the monolithic structure 202 in response to an electrical current being directed through the heating element 214. In some embodiments, the heating element 214 comprises a plurality of heating elements 214, each heating element 214 having a separate electrically conducting pathway extending through the insulating body 204 from the second side 212 of the insulating body to different interior regions of the insulating body 204 to provide localized thermal energy to the insulating body. In some embodiments, the plurality of heating elements 214 are located below the electrode 216 in the insulating body 204. In some embodiments, the plurality of heating elements 214 are arranged in a horizontal direction and/or a vertical direction within the insulating body 204 to obtain a desired thermal uniformity at a first side 210 of the insulating body 204. In some embodiments, the heating element 214 is located below the planar layer of the electrode 216 located in the insulating body 204. Stated another way, in some embodiments, within the insulating body 204, the heating element 214 extends through the insulating body 204 between the second side 212 and the planar layer of the electrode 216. As such, the region of the insulating body 204 comprising the heating element 214 may be referred to as a heat conducting region of the insulating body 204.

In some embodiments, the insulating body 204 includes a sidewall 218. In some embodiments, at least one of the plurality of heating elements 214 are further located adjacent the sidewall 218 within the insulating body 204. In some embodiments, at least one of the plurality of heating element 214 may circumferentially extend adjacent the sidewall 218 within the insulating body 204. In some embodiments, the heating element 214 may be configured to generate at least 500° C. Additionally, the insulating body 204 is formed around the heating element 214 to enable the insulating body 204 to distribute said heat generated by the heating element 214 throughout the insulating body 204 and at the first side 210. Accordingly, the insulating body 204 and the at least one conductive element 206 are capable of operating at temperatures of at least 500° C. In some embodiments, the insulating body 204 and the at least one conductive element 206 may be configured to operate at temperatures up to 500° C. In some embodiments, the insulating body 204 and the at least one conductive element 206 may be configured to operate at temperatures in excess of 500° C. In some embodiments, the insulating body 204 and the at least one conductive element 206 may be configured to operate at temperatures up to and including 550° C. In some embodiments, the insulating body 204 and the at least one conductive element 206 may be configured to operate at temperatures up to and including 1200° C.

In some embodiments, the at least one conductive element 206 may comprise an electrode 216. The electrode 216 is configured to produce an electrostatic field in response to an electrical charge. The electrode 216 extends from a second side of the insulating body towards a first side of the insulating body such that the at least one electrode substantially extends along a plane adjacent the first side within the insulating body. As such, the planar region of the insulating body 204 comprising the electrode 216 may be referred to as the electrically conductive region of the insulating body 204. In some embodiments, the electrode 216 comprises a plurality of electrodes 216. In some embodiments, the plurality of electrodes 216 comprise separate electrically conducting pathways extending through the insulating body 204 from a second side 212 of the insulating body and towards a first side 210 of the insulating body 204 such that the plurality of electrodes 216 substantially extend along a plane adjacent the first side 210 within the insulating body 204.

In some embodiments, the at least one conductive element 206 comprises a temperature measurement probe 220. In some embodiments, the temperature measurement probe 220 comprises at least one of a thermocouple, a resistant temperature detector, other temperature sensing device, or any combination thereof. In some embodiments, the at least one conductive element 206 comprises a plurality of temperature measurement probes 220. In some embodiments, each of the plurality of temperature measurement probes 220 comprises separate electrically conducting pathways extending through the insulating body 204 from a second side 212 towards a first side 210 of the insulating body.

The monolithic structure 202 is capable of operating at high temperatures. In some embodiments, the monolithic structure 202 may be capable of withstanding temperatures of over 500° C. For example, in some embodiments, the environment of the monolithic structure 202 may be maintained at such high temperatures during the manufacturing of semiconductor wafers.

The monolithic structure 202 does not comprise a bonding component. In some embodiments, the monolithic structure 202 does not comprise a bonding component between the insulating body 204 and the at least one conductive element 206. In some embodiments, the bonding component comprises a process or material applied to join together a first structure to a second structure after fabrication of at least one of the first structure or the second structure. For example, the monolithic structure 202 may not comprise an insulative layer and an electrode layer joined together after formation of at least one of the insulative layer and the electrode layer.

In this regard, in some embodiments, the monolithic structure 202 may be formed by additive manufacturing processes such that the resulting monolithic structure 202 does not have a bonding component after the monolithic structure 202 has sufficiently hardened. The monolithic structure 202 does not have bonding component(s) located therein as the bonding component may degrade or weaken over time in response to high temperatures and materially affect the integrity of the monolithic structure 202. In some embodiments, the bonding component may comprise, consist of, or essentially consist of, or may be selected from the group of adhesives, solders, filler metals, polymers (e.g., thermoplastics), glass bonding materials, or any combination thereof. In some embodiments, for example, adhesive includes epoxy.

In some embodiments, the monolithic structure 202 may further comprise at least one conduit 222. In some embodiments, the at least one conduit 222 is defined by at least one of the insulating body 204, the least one conductive element 206, or any combination thereof. In some embodiments, the at least one conduit 222 extends through the insulating body 204 adjacent a perimeter of the insulating body 204. In some embodiments, the at least one conduit 222 comprises one or more lift pin holes defined by the insulating body 204. The lift pin hole enables passage of an elongated member through the lift pin hole for removal of a substrate located on the first side 210 of the insulating body 204. In some embodiments, the at least one conduit 222 comprises a backside gas delivery hole defined by the insulating body 204. The backside gas delivery hole enables passage of a gas, such as a heat transfer gas, through the insulating body 204 to an underside of a substrate positioned on the first side 210 of the device 200. In some embodiments, the at least one conduit 222 comprises a dummy structure defined by the insulating body 204, the dummy structure is configured to provide uniform thermal, electrical and physical performance of the electrostatic chuck. In some embodiments, the at least one conduit 222 comprises at least one of a mounting fixture, bolt hole, flange, connector, alignment feature, optical pathway, or any combinations thereof.

In some embodiments, the monolithic structure 202 may further include one or more gas channels 224 defined by the insulating body 204. In some embodiments, the one or more gas channels 224 enables a gas to be directed through the channel between the substrate and the outer surface of the insulating body 204 at the first side 210. In some embodiments, the at least one conduit 222 may comprise the one or more gas channels 224 located at the first side 210 of the insulating body 204. In some embodiments, the structured pattern on the first side 210 of the insulating body 204 may comprise the one or more gas channels 224. In some embodiments, the insulating body 204 may comprise at least one gas channel 224 at the first side 210.

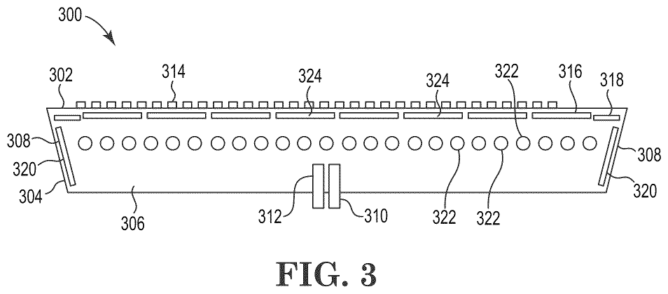

FIG. 3 is a sectional side view of a non-limiting embodiment of a device 300, according to some embodiments. As shown in FIG. 3, the device 300 comprises an electrostatic chuck 302 comprising a monolithic structure 304 comprising an insulating body 306 and at least one conductive element 308 located in the insulating body 306. In some embodiments, the insulating body 306 comprises a ceramic component. In some embodiments, the ceramic component comprises a ceramic material formed by additive manufacturing. In some embodiments, the at least one conductive element 308 comprises a metal component. In some embodiments, the metal component comprises a metal material formed by additive manufacturing. In some embodiments, the ceramic material and the metal material are selectively applied at each layer of the multi-layered additive manufacturing process to form the monolithic structure. In other embodiments, the ceramic material and the metal material are co-printed by an additive manufacturing process layer by layer to form the monolithic structure 304 having an insulating body 306 and at least one conductive element 308. As a result of being co-printed via an additive manufacturing process, the monolithic structure does not include a bonding component between the insulating body 306 and the at least one conductive element 308.

The at least one conductive element 308 may form a heat conductive region comprising at least one heating element 322, an electrically conductive region comprising at least one electrode 324, or any combination thereof. In some embodiments, the heat conductive region may be arranged in the insulating body 306 to maximize a thermal uniformity at a top surface of the electrostatic chuck 302 and delivered to the wafer. In some embodiments, the heat conductive region may be arranged in the insulating body 306 during additive manufacturing based on a predefined thermal characteristic at the electrostatic chuck 302 and the wafer. In some embodiments, the heat conductive region may comprise the at least one heating element 322 embedded in the insulating body 306. In some embodiments, a tracing of the heating element embedded in the insulating body 306 may be arranged during additive manufacturing to optimize the thermal uniformity of the electrostatic chuck 302. In some embodiments, the heat conductive region may comprise a sidewall heater 320. In some embodiments, the sidewall heater 320 may provide improved thermal uniformity at an edge of the electrostatic chuck 302.

The monolithic structure 304 may comprise a top surface and a bottom side opposite the top surface. The electrostatic chuck 302 may comprise at least one terminal 310. In some embodiments, the monolithic structure 304 may include the at least one terminal 310 formed from the metal material during the additive manufacturing process, the at least one terminal 310 being in connection with a corresponding one of the at least one conductive element 308. The at least one terminal 310 may be located in the insulating body 306 such that the at least one terminal 310 is accessible from the bottom surface of the insulating body 306. In some embodiments, the at least one terminal 310 may be positioned below a surface of the bottom surface of the electrostatic chuck 302 and an electrical plug connector may be placed in electrical communication with the at least one terminal 310 to deliver an electrical current to the corresponding at least one conductive element 308. In this regard, in some embodiments, the at least one terminal 310 may comprise electrode pins 312 that extend from the at least one terminal 310 through the bottom surface of the insulating body 306. In some embodiments, the at least one terminal 310 may be in communication with the heat conductive region and the at least one heating element 322. In some embodiments, the at least one terminal 310 may be in communication with the electrically conductive region and the at least one electrode 324. In some embodiments, the at least one terminal 310 comprises a first terminal in communication with the heat conductive region and a second terminal in communication with the electrically conductive region.

The electrostatic chuck 302 may not comprise a bonding component between the insulating body 306 and the at least one conductive element 308. In some embodiments, the bonding component may comprise, consist of, or essentially consist of, or may be selected from the group of an adhesive, a filler metal, a binding material, a glass bond, a sintered material, or any combination thereof. The electrostatic chuck 302 may be capable of operating at temperatures at or above 500° C. while maintaining thermal uniformity at the electrostatic chuck 302 and the wafer-level. The electrostatic chuck 302 may also be capable of providing adequate heater power at the edges of the electrostatic chuck 302. Accordingly, the electrostatic chuck 302 overcomes the temperature non-uniformities around features, such as from lift pin holes and backside gas holes that arise due to limitations in heater placement and issues with metal contaminants from heater materials diffusing to the wafer contact surface.

The electrostatic chuck 302 may comprise a coefficient of thermal expansion (CTE) between an insulating body 306 and a at least one conductive element 308 within 5-70%, or any range or subrange between 5-70%. For example, in some embodiments, the CTE between the insulating body 306 and the at least one conductive element may be within 5-60%, 5-50%, 5-40%, 5-30%, 5-20%, 5-10%, 10-70%, 10-60%, 10-50%, 10-40%, 10-30%, 10-20%, 20-70%, 20-60%, 20-50%, 20-40%, 20-30%, 30-70%, 30-60%, 30-50%, 30-40%, 40-70%, 40-60%, or 40-50%. In some embodiments, the electrostatic chuck 302 may comprise a coefficient of thermal expansion (CTE) within 50% between an insulating body 306 and a at least one conductive element 308. The ceramic material of the insulating body 306 and the metal material of the conductive elements 308 may be selected based on the CTE of the materials due to thermal stress failures that may result due to CTE mismatch. In some embodiments, the materials selected to form the electrostatic chuck 302 may be based on the CTE mismatch at high temperatures. In some embodiments, the materials selected to form the electrostatic chuck 302 may be based on the electrical performance at high temperatures. In some embodiments, high temperatures may comprise temperatures at or above 500° C.

The electrostatic chuck 302 may comprise a structured pattern on the top surface of the insulating body 306. The structured pattern may comprise an embossed surface. In some embodiments, the structured pattern may comprise a plurality of embossments 314 formed on the top surface. The plurality of embossments 314 may comprise a plurality of protrusions distributed across the top surface that are configured to contact a surface of a wafer. The plurality of embossments 314 reduces a surface area that contacts the wafer while allowing the wafer to be secured to the plurality of embossments 314 in response to an electrostatic force. In some embodiments, the top surface of the monolithic structure 304 may comprise a substantially planar surface comprising a plurality of channels defined by the plurality of embossments 314 formed at the top surface, the plurality of embossments 314 configured to contact a surface of a substrate (e.g., wafer). Additionally, in some embodiments, the plurality of channels may allow a gas, liquid, or both to be directed through the plurality of channels and between the plurality of embossments 314 when the wafer is positioned on the top surface. For example, a thermal gas may be delivered through the plurality of channels to improve the thermal heat transfer between the electrostatic chuck 302 and the wafer.

In some embodiments, a planarization process may be applied to the top surface such as to form the plurality of embossments 314 to provide a substantially planar surface for contacting the surface of the wafer. Planarization comprises the removal of surface topologies by flattening and smoothing a surface. In some embodiments, the plurality of embossments 314 may be formed by planarization of the insulating body 306. In some embodiments, the plurality of embossments 314 may be formed by polishing of the top surface to provide a substantially planar surface formed from the embossments. In some embodiments, the planarization removes a first layer from the plurality of embossments 314 and the polishing removes a second layer from the plurality of embossments 314 to further flatten and smooth the planar surface formed from the embossments to enable the electrostatic chuck 302 to contact the wafer without damaging the wafer.

In some embodiments, the device 300 includes a coating applied to the electrostatic chuck 302 and the monolithic structure 304 at least the top surface. In this regard, the coating may be applied to the top surface of the insulating body 306. In some embodiments, the plurality of embossments 314 are formed by a coating applied to the top surface of the insulating body 306. In other embodiments, the coating is polished to provide at least one of improved planarity, improved surface finish, improved density, improved precision of insulating layer thickness between the at least one conductive element and the first side, or any combinations thereof. In some embodiments, the coating comprises at least one of a dielectric layer, a metal diffusion barrier layer, a dielectric breakdown prevention layer, a mechanical wear resistant layer, or any combinations thereof.

The electrostatic chuck 302 may further comprise a dielectric layer 316. When the electrically conductive region is electrically biased with respect to a substrate by a voltage, a free electrostatic charge drifts through the dielectric layer 316 in response to the electric field generated at the electrically conductive region and the attractive force of the dielectric layer 316 combines with the electrostatic force of the insulating body 306 to provide a greater electrostatic force to secure the substrate. In some embodiments, the dielectric layer 316 may comprise one or more materials applied to the electrostatic chuck 302. In some embodiments, the dielectric layer 316 may be located on a surface of the electrostatic chuck 302 and the insulating body 306. In some embodiments, the dielectric layer 316 may be located on a first side of the electrostatic chuck 302. In some embodiments, the dielectric layer 316 may be located adjacent an electrically conductive region on the first side of the electrostatic chuck 302. In some embodiments, the dielectric layer 316 may be located over an electrode of the electrostatic chuck 302. In some embodiments, the dielectric layer 316 may be bonded to the monolithic structure 304 at the first side post-fabrication. In some embodiments, the dielectric layer 316 may be located on the top surface at the plurality of embossments 314.

The electrostatic chuck 302 may further comprise a diffusion barrier layer 318 located on a surface of the insulating body 306. The diffusion barrier layer 318 may prevent metal contaminants from reaching a substrate secured to the electrostatic chuck 302. For example, the diffusion barrier layer 318 may prevent metal contaminants from a dielectric layer 316 from reaching a substrate. In some embodiments, the diffusion barrier layer 318 may be located on the first side of the insulating body 306. In some embodiments, the diffusion barrier layer 318 may be located between the insulating body 306 and the dielectric layer 316. In some embodiments, the dielectric layer 316 may be located between the diffusion barrier layer 318 and the insulating body 306. Accordingly, in some embodiments, the diffusion barrier layer 318 may be applied onto the dielectric layer 316. In some embodiments, for example, the diffusion barrier layer 318 may comprise amorphous alumina deposited by atomic layer deposition.

It is to be appreciated by those having ordinary skill in the art that the configuration of the insulating body 306, the conductive elements 308 the at least one terminal 310, the plurality of embossments 314, the dielectric layer 316, and/or other components of the electrostatic chuck 302 is not intended to be limiting and the electrostatic chuck 302 may comprise other components and/or other configurations or arrangements without departing from the scope of this disclosure.

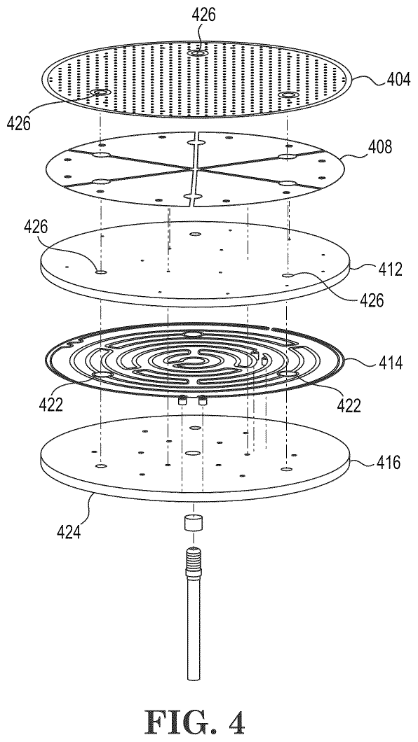

FIGS. 4-7 are schematic diagrams of a non-limiting embodiment of an electrostatic chuck, according to some embodiments.

FIG. 4 is an exploded view of an electrostatic chuck 400 having multiple layers (e.g. layers 404, 408, 412, 414 and 416). All or some of the layers may be formed using an additive manufacturing process. In some cases, the layers may be formed during a single additive manufacturing process (i.e. a single print). Layers formed by an additive manufacturing process have a monolithic structure having a unitary construction that is free from bonding components.

In some embodiments, as shown, top layer 404 comprises an insulating material. In some embodiments, second layer 408 comprises a conductive material such that it is a conductive layer. In some embodiments, conductive layer 408 is configured to be at least one electrode and is incorporated into (e.g., embedded) or onto the surface of layer 412 comprising an insulating material. In some embodiments, the insulating material used to form layer 412 is the same insulating material used to form top layer 404. In some embodiments, the insulating material used to form layer 412 is a different insulating material than that used to form layer 404.

In some embodiments, layer 414 is a conductive layer comprising a conductive material. In some embodiments, conductive layer 414 is incorporated inside insulating layer 412. In some embodiments, conductive layer 414 is embedded towards the bottom of the yellow layer. In some embodiments, conductive layer 414 is configured to be at least one heater. In some embodiments, the layer 414 comprises one or more collar-shaped elements 422. In some embodiments, the collar-shaped elements 422 are the electrical contacts to the heaters that extend through and/or into bottom layer 416 and facilitate connection with electrical power cables to the heater from the backside 424 of the electrostatic chuck 400.

In some embodiments, bottom layer 416 comprises an insulating material, which can be the same and/or different from the insulating material of the other layers (e.g. layers 404 and/or 412) discussed above. In some embodiments, bottom layer 416 is configured to allow the electrical connections to be incorporated into the part. In some embodiments, bottom layer 416 is constructed via an additive manufacturing process (e.g. 3D printing) to have open spaces or conduits such as, for examples, blind holes, that have conductive material on the inside wall surface. Such conduits within a monolithic structure are not achievable using conventional manufacturing methods and can only be achieved via additive manufacturing processes. In some embodiments, the conductive material lining the inner surface of the conduit is made thicker than is needed, so that the feature then later can be machined to make threads for connections.

In some embodiments, the additive manufactured part is built from the bottom up (i.e. beginning with bottom layer 416). In some embodiments, this involves starting with co-depositing or co-printing conductive and insulating material such that the collar shaped conductive features are created in substantially insulating material, as shown by way of example in layer 414. In some embodiments, as shown in FIG. 4, a plurality of circular vertical voids holes 426 are formed in conductive layer 414 that eventually go all the way through the chuck and serve as lift pin holes. In some embodiments, these holes 426 do not have conductive material on the inside wall (at any layer). In some embodiments, once these features are printed in bottom layer 416, the additive manufacturing incorporates a layer of conductive and insulating material to create the heaters. In some embodiments, there is a layer with substantially insulating material (insulating layer 412) except for the through holes 426, having no material, for the lift pin holes and conductive columns (not shown) that are configured to connect to the electrode layer, which is subsequently printed. In some embodiments, conductive layer 408 is an electrode layer and contains substantially conductive material with some insulating material disposed in between. As can be seen, conductive layer 408 also include the lift pin holes 426, which are empty spaces or voids in the layer 408. In some embodiments, as shown, there can be a precisely defined thin insulating layer (layer 404), which is solid filled with material expect for the lift pin holes 426. In some embodiments, the thickness of insulating layer 408 and the quality of the insulating material in layer 408 is optimized as, in some embodiments, layer 408 serves as the dielectric layer. In some embodiments, the additive manufactured process prints the embossments and the seal rings, and also the gas channel features on the top surface of layer 408.

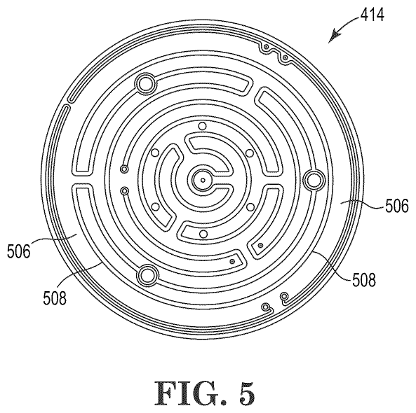

FIG. 5 depicts a heater layer 502 in accordance with some embodiments. In some embodiments, heater layer 502 includes an insulating material 506 and a conductive material 508 embedded within the same layer or such that the insulating material 506 and conductive material 508 lie within the same horizontal plane.

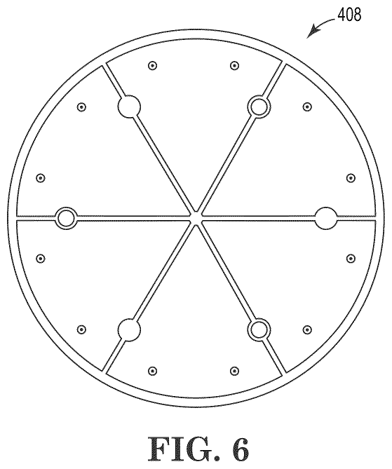

FIG. 6 depicts an electrode layer 602 including an insulating material 606 and a conductive material 608, according to some embodiments. Electrode layer 602 can be formed via an additive manufacturing process such as co-printing or co-depositing such that the electrode layer 602 is formed as monolithic structure having a unitary construction such the insulating material 606 and the conductive material lie in the same horizontal plane and the monolithic structure is free from bonding components.

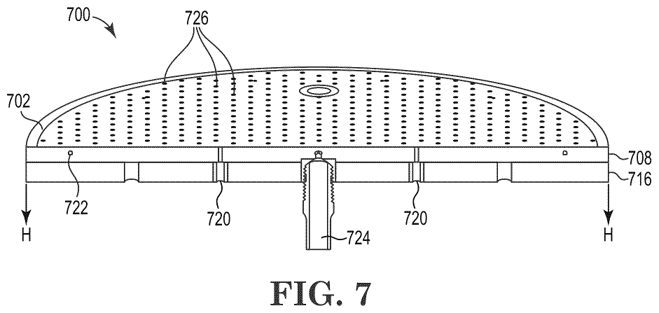

FIG. 7 depicts a side view of an electrostatic chuck 700 showing an electrode layer 708 connected to a bottom layer 716 with conductive columns 720, according to some embodiments. In some embodiments, two heater wires 722 are formed in the electrode layer 708. In some embodiments, a gas line connection 724 for backside gas is located in a center position of the chuck 700. In some embodiments, the gas line connection 722 is an internal channel routed through the insulating layer (not shown here) that is configured to connect to holes 726 on the top surface of the chuck 700. In some embodiments, the electrodes (not shown) are located close to the top surface. In some embodiments, the electrodes are separated by a thin insulating layer.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

1. An electrostatic chuck comprising:
an additive manufactured monolithic structure comprising:
an insulating body; and
at least one conductive element located within the insulating body,
wherein the monolithic structure does not comprise a bonding component between the insulating body and the at least one conductive element and wherein the electrostatic chuck is capable of withstanding temperatures at or above 500° C.

2. The electrostatic chuck of claim 1, wherein the at least one conductive element is a heater element and wherein the electrostatic chuck is capable maintaining a thermal uniformity across a wafer surface.

3. The electrostatic chuck of claim 1, wherein the additive manufactured monolithic structure further comprises at least one conduit, wherein the at least one conduit is defined by the insulating body and is free of any material.

4. The electrostatic chuck of claim 3, wherein the at least one conduit is at least one of a gas channel, a liquid channel, a connecting hole, a screw hole, a through-hole, a void, or any combination thereof.

5. The electrostatic chuck of claim 3, wherein the at least one conduit is a thermal shield structure within the insulating body, wherein the thermal shield structure is coextensive with and adjacent to an outer perimeter of the insulating body.

6. The electrostatic chuck of claim 1, wherein the insulating body comprises a ceramic material and the at least one conductive element comprises a metal material.

7. The electrostatic chuck of claim 6, wherein the ceramic material and the metal material are co-printed layer by layer to form the additive manufactured monolithic structure, wherein the ceramic material and metal material are co-printed such that ceramic material and metal material lie in a same horizontal plane.

8. The electrostatic chuck of claim 1, wherein the insulating body comprises at least one of:
alumina, zirconia, aluminum-nitride, aluminum-oxy-nitride, silicon-nitride, silicon-oxide, silicon-carbide, silicon-oxy-nitride, silicon-carbo-nitride, tungsten-carbide, titanium-oxide, hafnium silicate, zirconium silicate, zirconium silicate, hafnium dioxide, strontium dioxide, scandium dioxide, zirconium oxide, chromium oxide, yttrium oxide, iron oxide, barium oxide, barium titanate, tantalum oxide, or any combinations thereof and
the at least one conductive element comprises at least one of: aluminum, tungsten, nickel, stainless steel, silver, gold, tantalum, platinum, palladium, cobalt, titanium, copper, molybdenum, silicon, molybdenum disilicide, or any combinations thereof.

9. The electrostatic chuck of claim 1, wherein the insulating body has a resistivity of not less than about 10¹¹ Ohm-cm.

10. The electrostatic chuck of claim 1, wherein the at least one conductive element comprises:
at least one electrode, wherein the at least one electrode is configured to produce an electrostatic field in response to an electrical charge.

11. The electrostatic chuck of claim 10, wherein the at least one electrode is located beneath a top surface of the insulating body.

12. The electrostatic chuck of claim 1, wherein the at least one conductive element further comprises at least one heating element, wherein the at least one heating element is configured to provide thermal energy to the monolithic structure.

13. The electrostatic chuck of claim 12, wherein the at least one heating element is located below the at least one electrode in the insulating body.

14. The electrostatic chuck of claim 12, wherein the at least one heating element is located adjacent a sidewall within the insulating body.

15. A method comprising:
depositing a ceramic material to form an insulating body, and
depositing a metal material to form at least one conductive element located in the insulating body,
wherein the ceramic material and the at least one conductive element define a monolithic structure having a unitary construction free from bonding components and capable of withstanding temperatures at or above 500° C.

16. The method of claim 15, further comprising forming a least one conduit free from any material within the monolithic structure.

17. The method of claim 15, wherein an additive manufacturing process is used to deposit the ceramic material and deposit the metal material.

18. The method of claim 17, wherein the ceramic material and the metal material are co-printed layer by layer such that the ceramic material and the metal material lie within a same horizontal plane.

19. The method of claim 15, further comprising:
applying a coating onto a top surface of the insulating body.

20. The method of claim 15, wherein the monolithic structure forms at least a part of an electrostatic chuck.
